(19) United States
(12) Patent Application Publication
(10) Pub. No.: US 2010/0197050 A1
(43) Pub. Date: Aug. 5, 2010

(54) METHOD OF FORMING SEMICONDUCTOR THIN FILM AND INSPECTION DEVICE OF SEMICONDUCTOR THIN FILM

(75) Inventors: Nobuhiko Umezu, Kanagawa (JP); Yoshio Inagaki, Kanagawa (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/695,347

(22) Filed: Jan. 28, 2010

(30) Foreign Application Priority Data
Feb. 5, 2009 (JP) 2009-024470

(51) Int. Cl. H01L 21/66; H01L 21/268; H01L 21/428; G06F 19/00

(52) U.S. Cl. 438/16; 702/81; 257/E21.347; 257/E21.475; 257/E21.521

(57) ABSTRACT

A method of forming a semiconductor thin film includes the steps of: forming an amorphous semiconductor thin film on a substrate; partially forming a crystalline semiconductor thin film for each element region by irradiating laser light to the amorphous semiconductor thin film to selectively perform a heating treatment on the amorphous semiconductor thin film, and crystallizing an amorphous semiconductor thin film corresponding to an irradiation region; and inspecting crystallinity of the crystalline semiconductor thin film. The inspection step includes the steps of obtaining an optical step based on an optical phase difference between a crystallized region and an uncrystallized region by irradiating light to the crystalline semiconductor thin film and the amorphous semiconductor thin film, and evaluating one or both of sorting of the crystalline semiconductor thin film and control of crystallinity of the crystalline semiconductor thin film, based on the obtained optical step.

### BACKGROUND OF THE INVENTION

1. Field of the Invention

The present invention relates to a method of forming a semiconductor thin film suitable, for example, for manufacture of a TFT (thin film transistor) substrate used in a liquid crystal display or an organic EL (electroluminescence) display, and an inspection device of such a semiconductor thin film.

2. Description of the Related Art

In an active matrix type liquid crystal display and an organic EL display using organic EL elements, a TFT substrate is used. In this TFT substrate, an amorphous semiconductor thin film or a polycrystalline semiconductor thin film having a relatively-small grain diameter is formed on a substrate, and the semiconductor thin film is crystal-grown by irradiating a laser beam to the semiconductor thin film for annealing. Thereby, a TFT as a drive element is formed.

As a light source in such an annealing device using a laser beam, an excimer laser in which an absorption rate of a semiconductor thin film is high, and a large pulse light output is obtained has been used. However, since this excimer laser is a gas laser, output intensity is varied for each pulse. Thus, the variation of characteristics is generated in the TFT which is formed through the use of the excimer laser, and there is a shortcoming that display non-uniformity is likely to be generated in a display using the TFT. In particular, since the organic EL display is driven by current in many cases, such a variation of characteristics is a major factor causing a decrease in a yield rate during mass production.

Thus, for the purpose of solving degradation of image quality caused by the variation of the pulse intensity in the gas laser, there has been proposed an annealing device in which a semiconductor laser having high output stability is used as a light source (for example, Japanese Unexamined Patent Publication No. 2003-332235). However, since the light output obtained from the semiconductor laser is extremely small in comparison with that of the excimer laser or the like, the size of a beam at the time of an annealing treatment becomes small. Thus, annealing time per unit area of the TFT substrate is increased, and issues such as a decrease in productivity and an increase in manufacture cost are generated.

Thus, for the purpose of obtaining a high throughput in the annealing treatment, there has been proposed an annealing method in which scanning time is reduced and productivity is increased by arranging a plurality of laser light sources adjacent to each other, and irradiating a plurality of laser beams by the plurality of laser light sources to a plurality of regions on an amorphous semiconductor thin film at the same time (for example, Japanese Unexamined Patent Publication No. 2004-153150).

On the other hand, a method of controlling crystallinity of the semiconductor thin film using such a semiconductor laser has been performed with a monitoring means monitoring laser beam intensity which is installed in the annealing device. For example, in a method of monitoring the laser beam intensity described in Japanese Unexamined Patent Publication No. 2005-101202, a single intensity measurement section is used for optical paths of a plurality of laser optical systems. One intensity measurement section is shifted on the optical path of each laser optical system to be able to receive light on each optical path, and thus it is possible to measure respective irradiation energy of the plurality of laser optical systems with one intensity measurement section.

For example, in Japanese Unexamined Patent Publication No. 2002-319606, there has been proposed a device in which degree of crystallinity in an anneal region is evaluated by obtaining the level of gradation of luminance based on irradiation light in the anneal region (crystallized region). Specifically, the degree of crystallinity is evaluated based on a pattern by the level of crystallinity in the crystallized region.

### SUMMARY OF THE INVENTION

However, in the case where the annealing treatment is performed by using a plurality of laser beams as in Japanese Unexamined Patent Publication No. 2004-153150, there is an individual difference of divergence angle of irradiation light in individual laser light sources. Moreover, even in the case where a uniform-irradiation optical system is provided so as to correct such an individual difference, adjustment error or the like is generated. As a result, when the annealing treatment is performed with a plurality of laser beams, for example, for the purpose of improving tact, the variation of device characteristics is generated. In a display panel using such a device, there may be a visible difference in some cases. Thus, in a step immediately after the annealing treatment which is performed before forming the device, a method of detecting and determining crystallinity distribution on individual devices processed with different beams, or an index corresponding thereto is desired.

In the case of Japanese Unexamined Patent Publication No. 2005-101202, since only the intensity (power) of the laser beams by the individual laser light sources is monitored, it is difficult to monitor the slight difference of power density on the plane of an object to be irradiated due to focus positions, aberration of the optical systems, or the like. Therefore, such a difference of the power density becomes a difference of the anneal effect to the object to be irradiated (semiconductor thin film), and a difference of crystallinity depending on a position on the semiconductor thin film. As a result, the characteristics of the formed TFT are varied depending on each laser beam. Such a difference in characteristics of the TFT may cause display non-uniformity in the display. Such a difference of the laser anneal effect to the semiconductor thin film (difference of the effect depending on a position on the thin film) may be generated not only in the case where the plurality of laser light sources are used to perform the annealing treatment as described above, but also in the case where a single laser light source is used to perform the annealing treatment.

Moreover, in Japanese Unexamined Patent Publication No. 2002-319606, the above-described characteristic pattern does not appear in the crystallized region in some cases (for example, in the case of microcrystal having a grain diameter of several tens of nm or smaller). Thus, the degree of crystallinity may not be evaluated in such a case, and is it desirable to provide an evaluation method with higher accuracy.

In view of the foregoing, it is desirable to provide a method of forming a semiconductor thin film capable of evaluating crystallinity more accurately in comparison with that of the existing art, in formation of a semiconductor thin film utilizing crystallinity by laser anneal, and an inspection device of a semiconductor thin film.

According to an embodiment of the present invention, there is provided a method of forming a semiconductor thin film including the steps of: forming an amorphous semiconductor thin film on a substrate; partially forming a crystalline semiconductor thin film for each element region by irradiating laser light to the amorphous semiconductor thin film to selectively perform a heating treatment on the amorphous semiconductor thin film, and crystallizing an amorphous semiconductor thin film corresponding to an irradiation region; and inspecting crystallinity of the crystalline semiconductor thin film. The inspection step includes the steps of obtaining an optical step based on an optical phase difference between a crystallized region and an uncrystallized region by irradiating light to the crystalline semiconductor thin film and the amorphous semiconductor thin film, and evaluating one or both of sorting of the crystalline semiconductor thin film and control of crystallinity of the crystalline semiconductor thin film, based on the obtained optical step.

In the method of forming a semiconductor thin film according to the embodiment of the present invention, after forming the amorphous semiconductor thin film on the substrate, the crystalline semiconductor thin film is partially formed for each element region by irradiating the laser light to the amorphous semiconductor thin film to selectively perform the heating treatment on the amorphous semiconductor thin film, and crystallizing the amorphous semiconductor thin film corresponding to the irradiation region. After that, crystallinity of the crystalline semiconductor thin film is inspected. Here, in the inspection step, an optical step based on the optical phase difference between the crystallized region and the uncrystallized region is obtained by irradiating the light to the crystalline semiconductor thin film and the amorphous semiconductor thin film, and one or both of sorting of the crystalline semiconductor thin film and control of crystallinity of the crystalline semiconductor thin film is evaluated based on the obtained optical step. In this manner, the crystalline semiconductor thin film is evaluated by using the optical step based on the optical phase difference between the crystallized region and the uncrystallized region. Thereby, the evaluation including the distribution of the microcrystalline is possible. Therefore, the sorting more accurate compared to that of the existing art is realized, and a new control (control of crystallinity) may be realized.

According to the embodiment of the present invention, there is provided an inspection device of a semiconductor thin film including: a stage mounting a substrate on which a crystalline semiconductor thin film is partially formed for each element region by irradiating laser light to an amorphous semiconductor thin film on the substrate to selectively perform a heating treatment on the amorphous semiconductor thin film, and crystallizing an irradiation region; a light source irradiating light to the crystalline semiconductor thin film and the amorphous semiconductor thin film; a derivation section obtaining an optical step based on an optical phase difference between a crystallized region and an uncrystallized region based on the light emitted from the light source; and an evaluation section evaluating one or both of sorting of the crystalline semiconductor thin film and calculation of a control amount of crystallinity of the crystalline semiconductor thin film based on the optical step obtained in the derivation section.

In the inspection device according to the embodiment of the present invention, in the substrate on which the crystalline semiconductor thin film is partially formed for each element region, the light is irradiated from the light source to the crystalline semiconductor thin film and the amorphous semiconductor thin film. Based on the light irradiated from the light source, the optical step based on the optical phase difference between the crystallized region and the uncrystallized region is obtained. Based on the obtained optical step, one or both of the sorting of the crystalline semiconductor thin film and the calculation of the control amount of crystallinity of the crystalline semiconductor thin film is evaluated. In this manner, the crystalline semiconductor thin film is evaluated by using the optical step based on the optical phase difference between the crystallized region and the uncrystallized region. Thereby, the evaluation including the distribution of the microcrystal is possible. Therefore, the sorting more accurate compared to that of the existing art is realized, and a new control (control of crystallinity) may be realized.

According to the method of forming a semiconductor thin film of the embodiment of the present invention, in the inspection step inspecting the crystallinity of the crystalline semiconductor thin film, by irradiating the light to the crystalline semiconductor thin film and the amorphous semiconductor thin film, the optical step based on the optical phase difference between the crystallized region and the uncrystallized region is obtained, and, based on the obtained optical step, one or both of sorting of the crystalline semiconductor thin film and control of crystallinity of the crystalline semiconductor thin film is evaluated. Thus, the sorting more accurate compared to that of the existing art is realized, and the new control (control of crystallinity) may be realized. Therefore, in formation of the semiconductor thin film utilizing crystallinity by laser annealing, it is possible to evaluate the crystallinity more accurately in comparison with the existing art, and thereby it is possible to improve the yield rate.

According to the inspection device of the embodiment of the present invention, the light is irradiated from the light source to the crystalline semiconductor thin film and the amorphous semiconductor thin film, and the optical step based on the optical phase difference between the crystallized region and the uncrystallized region is obtained. Based on the obtained optical step, one or both of the sorting of the crystalline semiconductor thin film and the calculation of the control amount of crystallinity of the crystalline semiconductor thin film is evaluated. Thus, the sorting more accurate compared to that of the existing art is realized, and the new control (control of crystallinity) may be realized. Therefore, in formation of the semiconductor thin film utilizing crystallinity by laser annealing, it is possible to evaluate the crystallinity with high accuracy in comparison with the existing art, and thereby it is possible to improve the yield rate.

Other and further objects, features and advantages of the invention will appear more fully from the following description.

### BRIEF DESCRIPTION OF THE DRAWINGS

FIG. 1 is a view illustrating the overall configuration of an inspection device of a semiconductor thin film according to an embodiment of the present invention.

FIG. 2 is a cross-sectional view illustrating a part of a major step in a method of forming a semiconductor thin film according to the embodiment of the present invention.

FIG. 3 is a cross-sectional view illustrating a step subsequent to FIG. 2.

FIG. 4 is a cross-sectional view illustrating a step subsequent to FIG. 3.

FIG. 5 is a flow chart illustrating an example of a step subsequent to FIG. 4 (inspection step).

FIGS. 6A and 6B are characteristic views illustrating an example of a distribution aspect of an optical step in a crystallized region to an uncrystallized region.

FIG. 7 is a characteristic view illustrating an example of the relationship between a wavelength of irradiation light and reflectance.

FIGS. 8A and 8B are characteristic views illustrating an example of the correlation between irradiation intensity, optical step index, and electric properties used at the time of the inspection step illustrated in FIG. 5.

FIG. 9 is a view for comparing and explaining an evaluation method according to the embodiment of the present invention and an existing evaluation method.

FIG. 10 is a cross-sectional view illustrating an example of the configuration of a TFT substrate including the semiconductor thin film formed with the steps of FIG. 2 to FIG. 5.

### DETAILED DESCRIPTION OF THE PREFERRED EMBODIMENTS

Hereinafter, an embodiment of the present invention will be described in detail with reference to the accompanying drawings. The description will be made in the following order:
1. Embodiment (example of a method of forming a semiconductor thin film including an inspection step using an optical step)
2. Modification and application example

### 1. Embodiment

Configuration Example of Inspection device of Semiconductor Thin Film

FIG. 1 illustrates the overall configuration of an inspection device (inspection device 1) of a semiconductor thin film according to an embodiment of the present invention. The inspection device 1 is applied, for example, to a silicon semiconductor thin film formed during a manufacture step of a thin film transistor having the bottom gate structure (bottom gate type TFT). Specifically, the inspection device 1 is an inspection device of crystallinity applied to a Si (silicon) thin film substrate 2. In the Si thin film substrate 2, after forming an a-Si (amorphous silicon) film (amorphous semiconductor thin film) on a transparent substrate, laser light is selectively irradiated to the a-Si film to perform the annealing treatment, and thereby an irradiation region (irradiation region 41 which will be described later) is crystallized. In the Si thin film substrate 2, a p-Si (polysilicon) film (crystalline semiconductor thin film) is partially formed for each element region (pixel).

The inspection device 1 includes a movable stage 11, an LED (light emitting diode) 12, a typical light interference microscope system, a dedicated image processing computer 15, and a control computer 16. The above-described light interference microscope system includes an objective lens 13 for a light interferometer, and a CCD (charge coupled device) camera 14. In the following description, although the p-Si film as an example of a crystallized Si thin film is used for the description, a microcrystalline Si film may be used.

The movable stage 11 mounts (supports) the Si thin film substrate 2 to be inspected, and may arbitrarily move in an X-axis direction and a Y-axis direction in the figure in response to a control signal S supplied from the control computer 16 which will be described later.

The LED 12 is a light source irradiating light (irradiation light Lout) to the Si thin film substrate 2 through a beam splitter 17 from the position above the movable stage 11, and irradiates the light having a wavelength region of a center wavelength of, for example, approximately 400 nm to 600 nm both inclusive. The LED 12 is preferably used together with a bandpass filter (not illustrated in the figure) selected according to accuracy of a measurement region in the thickness direction, and thereby irradiates the irradiation light Lout. As a light source, a lamp illuminator of a microscope or the like may be used in substitution for the LED with high luminance.

The objective lens 13 is an optical element magnifying and detecting the irradiation light Lout (reflection light) emitted from the LED 12 and reflected on the Si thin film substrate 2. The CCD camera 14 is a camera highly sensitive to light having a wavelength region of approximately 400 nm to 600 nm both inclusive, and includes a CCD image sensor as an image pick-up element inside thereof. With such a configuration, in the light interference microscope, a reflection image and an interference fringe image of the a-Si film (uncrystallized region) and the p-Si film (crystallized region) in the Si thin film substrate 2 are picked up.

The image processing computer 15 evaluates one or both of sorting of the p-Si film and calculation of a control amount of crystallinity based on the interference fringe image of the a-Si film and p-Si film obtained with the objective lens 13 and the CCD camera 14. In such evaluation (inspection), specifically, an interference fringe image data D1 supplied from the CCD camera 14 is captured, and the distribution of the interference fringe is analyzed to obtain an optical step between the p-Si film (crystallized region) and the a-Si film (uncrystallized region) formed on the Si thin film substrate 2. Based on the obtained optical step, the determination of whether the p-Si film formed on the Si thin film substrate 2 is non-defective or defective is performed. Alternatively, for example, in the case of EQC (equipment quality control) process, quantitative feed back process of annealing intensity is performed. The inspection process by the image processing computer 15 will be described later in detail.

The control computer 16 performs lighting control of the irradiation light Lout from the LED 12, control of a movement position of the LED 12, the objective lens 13, and the CCD camera 14, switching control of the objective lens 13, and the like. Among them, as the control of the movement position, specifically, the control computer 16 performs the control so as to relatively displace the LED 12, the objective lens 13, and the CCD camera 14 to the Si thin film substrate 2 mounted on the movable stage 11.

Here, the LED 12 corresponds to a specific example of “light source” of the embodiment of the present invention. The objective lens 13, the CCD camera 14, and the image processing computer 15 correspond to a specific example of “derivation section” of the embodiment of the present invention. The objective lens 13, the CCD camera 14, and the beam splitter 17 correspond to a specific example of “optical system of derivation section” of the embodiment of the present invention. The image processing computer 15 corresponds to a specific example of “evaluation section” of the embodiment of the present invention. The control computer 16 corresponds to a specific example of “control section ” of the embodiment of the present invention.

Example of Method of Forming Semiconductor Thin Film

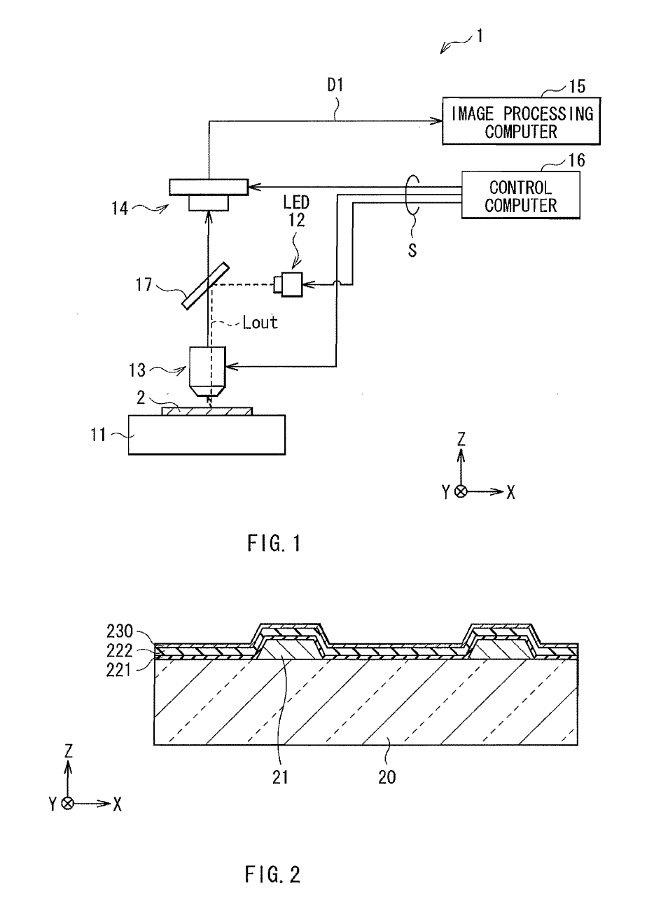

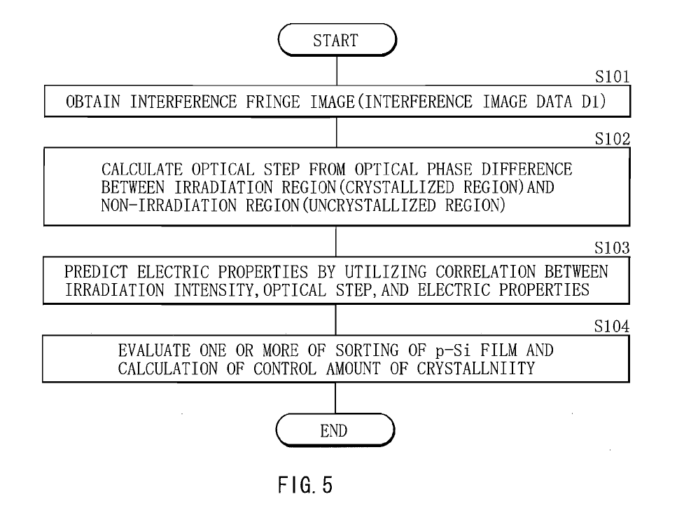

Next, with reference to FIGS. 2 to 9, the method of forming the semiconductor thin film according to the embodiment of the present invention, which includes the inspection step using the inspection device 1 illustrated in FIG. 1, will be described. Here, FIGS. 2 to 4 illustrate a cross-sectional view (Z-X cross-sectional view) of a part of a major step in the method of forming the semiconductor thin film of this embodiment. FIG. 5 is a flowchart illustrating an example of the inspection step as a step subsequent to FIG. 4.

Step of Forming Semiconductor Thin Film

First, as illustrated in FIG. 2, for example, on a transparent substrate 20 made of a glass substrate or the like, a gate electrode 21, gate insulating films 221 and 222, and an a-Si flim 230 are formed in this order through the use of, for example, photolithography method. At this time, as the transparent substrate 20, a substrate having the size of, for example, approximately 550 mm×650 mm is used. The gate electrode 21 is composed of, for example, molybdenum (Mo), the gate insulating film 221 is composed of, for example, silicon nitride (SiNₓ), and the gate insulating film 222 is composed of, for example, silicon oxide (SiO₂).

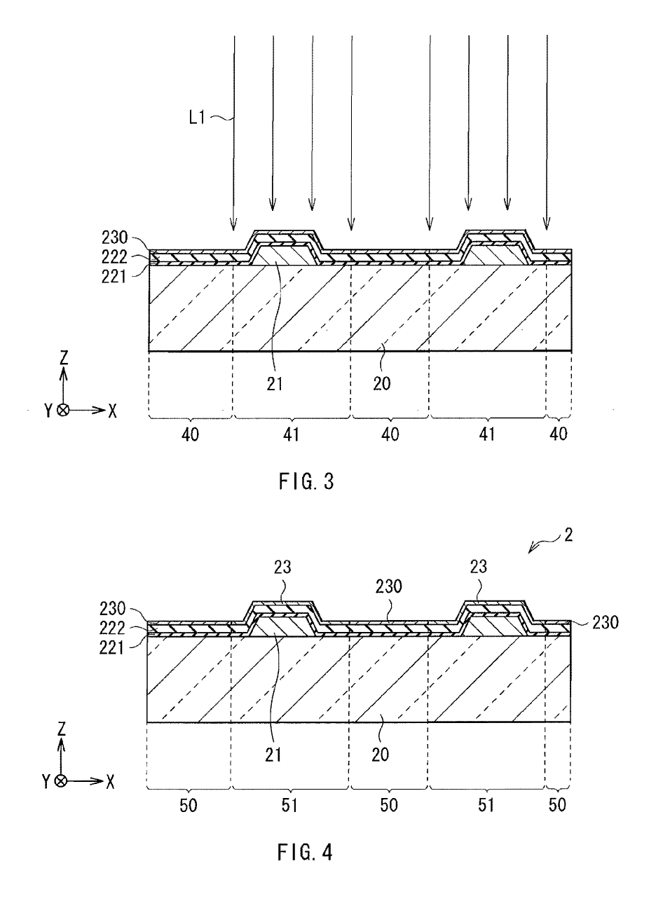

Next, as illustrated in FIG. 3, a laser light L1 is partially irradiated to the a-Si film 230 on the transparent substrate 20 through the use of a semiconductor laser light source not illustrated in the figure to selectively perform the annealing treatment (heating treatment). Thereby, the a-Si film 230 is partially crystallized for each element region (corresponding to a pixel, in the case where the Si thin film substrate 2 is applied to a display). Specifically, for example, as illustrated in FIG. 4, since the annealing treatment is performed on an irradiation region 41 of the laser light L1, the irradiation region 41 is crystallized and becomes a crystallized region 51 in which a p-Si film 23 is formed. On the other hand, since the annealing treatment is not performed on a non-irradiation region 40 of the laser light L1, the non-irradiation region 40 is not crystallized and becomes an uncrystallized region 50 in which the a-Si film 230 is formed and remains.

Inspection Step

Next, for example, as illustrated in steps S101 to S104 in FIG. 5, the inspection of crystallinity condition (degree of crystallinity) of the p-Si film 23 formed on the transparent substrate 20 is performed (inspection process is performed) through the use of the inspection device 1 illustrated in FIG. 1.

Specifically, the Si thin film substrate 2 in which the p-Si film 23 is formed is mounted on the movable stage 11. Next, the irradiation light Lout is irradiated (for example, collectively irradiated) with the LED 12 to the p-Si film (crystallized region 51) and the a-Si film (uncrystallized region 50) through the beam splitter 17 from the position above the movable stage 11 (mount plane side of the Si thin film substrate 2). The light reflected on the movable stage 11 and the Si thin film substrate 2 is received and an image is picked up with the objective lens 13 and the CCD camera 14. Thereby, in the image processing computer 15, the interference fringe image (interference fringe image data D0 of the p-Si film 23 (crystallized region 51) and the a-Si film 230 (uncrystallized region 50) is obtained (S101 of FIG. 5). At this time, the LED 12, the objective lens 13, the beam splitter 17, and the CCD camera 14 may be relatively displayed to the Si thin film substrate 2 mounted on the movable stage 11 in response to the control signal S supplied from the control computer 16. Thereby, it is possible to obtain the interference fringe image at a plurality of points on the p-Si film 23.

Next, with the image processing computer 15, based on the obtained interference fringe image, the optical step and the distribution of the optical step are obtained from optical phase difference generated by physical property difference between the p-Si film 23 (crystallized region 51) and the a-Si film 230 (uncrystallized region 50) (Step S102). Specifically, the image processing computer 15 calculates an optical phase difference Δφ between the p-Si film 23 and the a-Si film 230 by using formula (1) below, and obtains the optical step and the distribution thereof from the calculated optical phase difference Δφ. This is because crystallinity of a microcrystalline Si film or a Si film largely depends on energy density (irradiation intensity) at the time of the annealing treatment, and the refractive index of the microcrystalline Si film or the Si film changes according to the difference of crystallinity.

Δφ=(2π/λ)×d×Δn (1)

(Δφ: optical phase difference; d: physical step; and Δn: refractive index difference due to physical property difference)

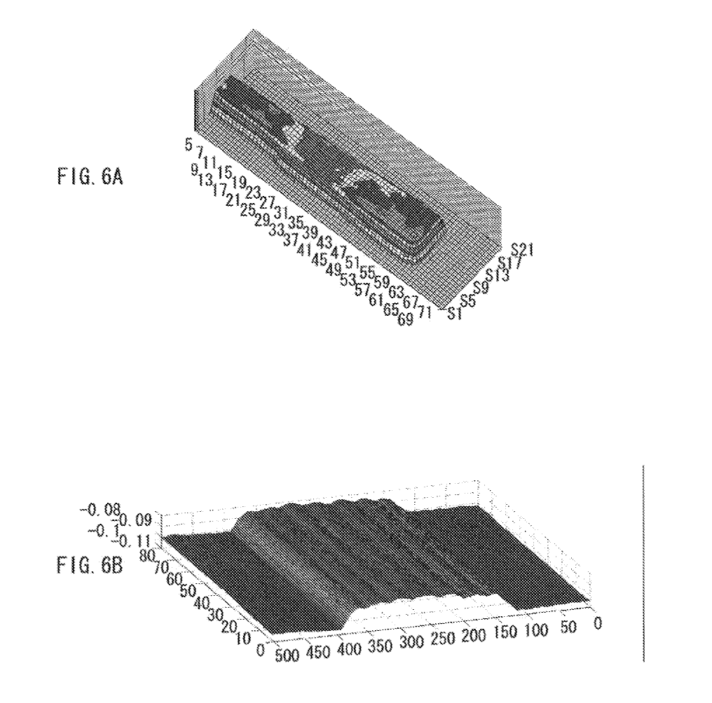

Therefore, for example, as illustrated in FIGS. 6A and 6B, the optical phase difference (optical step) is different from each other in the crystallized region 51 (irradiation region 41) and the uncrystallized region 50 (non-irradiation region 40). FIG. 6A illustrates an example of a distribution aspect of the optical phase difference (optical step) in a region of a predetermined base pattern in the crystallized region 51. FIG. 6B illustrates an example of a distribution aspect of the optical phase difference (optical step) in a region other than the predetermined base pattern in the crystallized region 51.

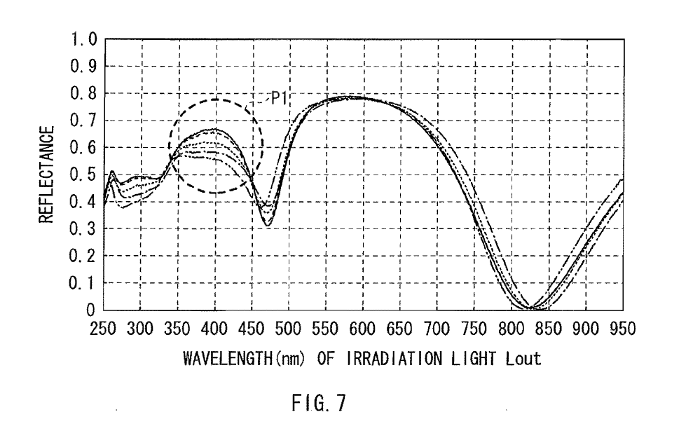

In the step of obtaining the optical step, as the irradiation light Lout, it is preferable to use light having a wavelength region of approximately 350 nm to 400 nm both inclusive. This is because, as indicated by reference numeral P1 in FIG. 7, since the reflectance change according to the annealing intensity is maximized in such a wavelength region, the optical phase difference (optical step) also becomes large, resulting that the measurement sensitivity may be improved.

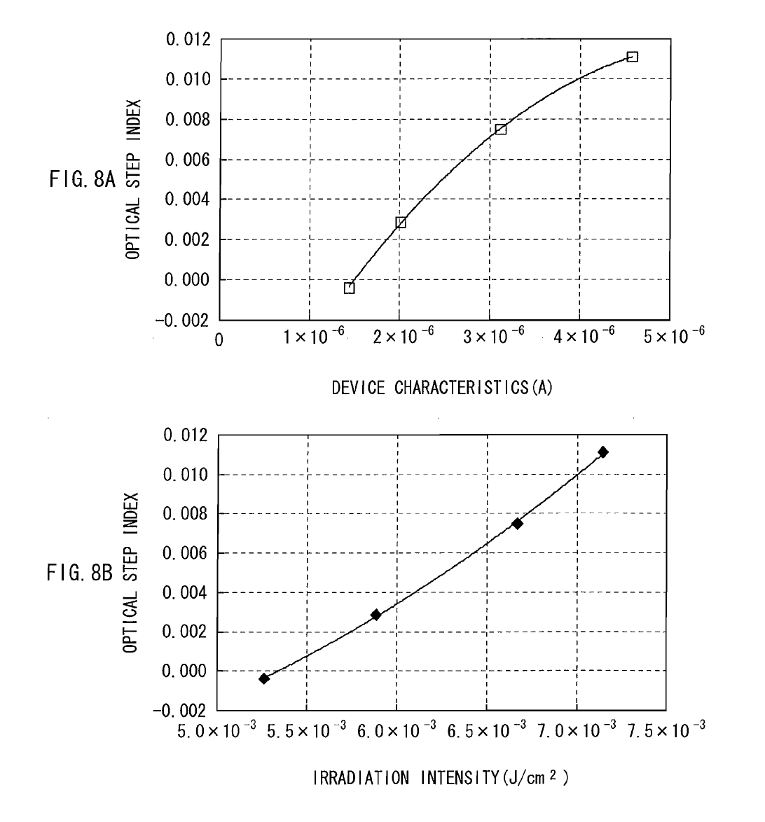

Next, with the image processing computer 15, based on the obtained optical step, electric properties expected to be obtained in the p-Si film 23 are predicted by utilizing, for example, the correlation illustrated in FIGS. 8A and 8B (step S103). As such electric properties (device electric properties), for example, there is a current value of a current flowing between a source and a drain in the TFT. Specifically, the image processing computer 15 predicts the electric properties by utilizing the correlation between the optical step, the light irradiation intensity at the time of obtaining the optical step, and the electric properties expected to be obtained in the p-Si film 23 (step S103). A characteristic graph of the correlation as illustrated in FIGS. 8A and 8B is formed in advance.

Here, for example, in the case where the variation of the electric properties between TFTs adjacent to each other is small as approximately 3% or less, for example, as illustrated in FIGS. 8A and 8B, it is seen from the experimental result that items (1) to (3) below are established.
(1) The process intensity (irradiation intensity) and the (reflective) optical step indicates extremely-good correlation.
(2) The device electric properties are increased as the (reflective) optical step is increased.
(3) When the process intensity (irradiation intensity) is controlled so that the (reflective) optical step has a specific value all the time, the device electric properties also become constant.

From these, it can be seen that, by recognizing in advance the correlation between the process intensity (irradiation intensity) and the (reflective) optical step (FIG. 8B), the device electric properties may be predicted with accuracy of 1% or less before the device is manufactured to the last step. Therefore, the manufacture yield rate is improved with upstream control.

In the case of the display using the TFT, typically, when the luminance difference between pixels adjacent to each other is 3% or less, it is said that the difference is not viewable. That is, when the current value difference in TFTs is 3% or less, the difference is not viewable. Thus, for example, it can be seen that a curve corresponding to the above-described item (2) (FIG. 8A) is formed in advance to obtain a differential coefficient of the curve, and the difference in the optical step is set within a range of 0.01/differential coefficient, thereby the current value difference of 1% or less is realized in TFTs.

Next, with the image processing computer 15, one or both of sorting of the p-Si film 23 and calculation of the control amount of crystallinity is evaluated by utilizing the correlation between the (reflective) optical step, the irradiation intensity, and the device electric properties (step S104). Specifically, sorting that whether the p-Si film 23 is non-defective or defective is performed according to the value of the device electric properties predicted in step S103, or, for example, in the case of the EQC process, the quantitative feed back process of the annealing intensity is performed. Thereby, the inspection process of crystallinity of the p-Si film 23 formed on the transparent substrate 20 is finished.

In this manner, in this embodiment, after forming the a-Si film 230 on the transparent substrate 20, the laser light L1 is partially irradiated to the a-Si film 230 to selectively perform the annealing treatment (heating treatment). Thereby, a part of the a-Si film 230 corresponding to the irradiation region 41 is crystallized, and the p-Si film 23 is partially formed for each element region (pixel). After that, crystallinity of the p-Si film 23 is inspected with the inspection device 1 (inspection process is performed). Here, in the inspection process, the irradiation light Lout is irradiated with the LED 12 to the p-Si film 23 and the a-Si film 230 from the surface side of the movable stage 11 which mounts the transparent substrate 20 (Si thin film substrate 2) on which the p-Si film 23 and the a-Si film 230 are formed. The reflection light reflected on the p-Si film 23 or the a-Si film 230 through the beam splitter 17 is received with the CCD camera 14 through the objective lens 13. Thereby, the interference fringe image (interference image data D1) of the p-Si film 23 and the a-Si film 230 is obtained. The image processing computer 15 which has obtained the interference fringe data D1 obtains the (reflective) optical step between the p-Si film 23 (crystallized region 51) and the a-Si film 230 (uncrystallized region 50) to perform the evaluation of the p-Si film 23 based on the obtained (reflective) optical step. Specifically, one or both of sorting of the p-Si film 23 and calculation of the control amount of crystallinity is evaluated. In this manner, the p-Si film 23 is evaluated based on the optical step between the crystallized region 51 and the uncrystallized region 50. Thereby, the evaluation including the distribution of the microcrystal is possible. Therefore, the sorting more accurate compared to that of the existing art is realized, and a new control (control of crystallinity) may be realized. That is, for example, even in the case of the microcrystalline Si film having a grain diameter of several tens of nm or smaller, accurate sorting is performed.

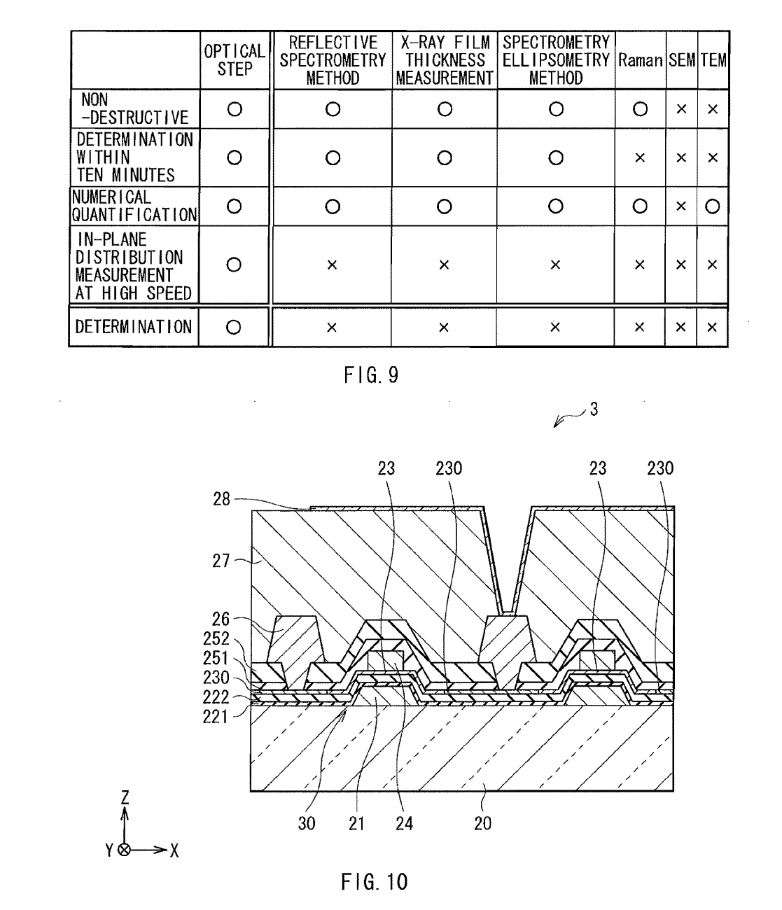

By performing the sorting based on such a (reflective) optical step, for example, as illustrated in FIG. 9, in-plane distribution measurement and evaluation are realized at remarkably-high speed in comparison with those of the existing evaluation methods, and the non-contact non-destructive fine-region inspection is realized, thereby numerical quantification is possible. The above-described “existing evaluation methods” include reflective spectrometry method, X-ray film thickness measurement method, spectrometry ellipsometry method, Raman spectrometry method, SEM (scanning electron microscope) method, and TEM (transmission electron microscope) method. In the existing evaluation methods, in the case of low-temperature p-Si, there is no method capable of non-destructive non-contact in-line evaluation at high speed with high accuracy, and capable of process monitor in an annealing process of a large substrate. Specifically, SEM method is a destructive inspection, and uses secco etching so that it takes too much time. Moreover, since surface morphology is observed in SEM method, quantitative evaluation is difficult. In terms of the non-contact non-destructive inspection, although X-ray film thickness measurement method, reflective spectrometry method, spectrometry ellipsometry method, and Raman spectrometry method may be cited, the accuracy with which the variation of the annealing light source of 1% or less may be detected is not achievable. Since the measurement is performed for each point, it takes tremendous time to evaluate the in-plane distribution in a pattern region, and the in-line evaluation is unusable. Moreover, in the case of microcrystalline Si, since the grain diameter is small by one order of magnitude in comparison with that of low-temperature Si, the evaluation with high accuracy is more difficult. In low-temperature p-Si, linearity and/or periodicity in a spatial structure of a surface of a formed film is found out, and there has been proposed a method of evaluating a p-Si film by evaluating the linearity and/or the periodicity of the spatial structure of this surface. However, in the case of microcrystal, such a characteristic phenomenon is not exhibited, and the evaluation is difficult. Only one method which has been proposed is the optical step evaluation through the use of reflective spectrometry measurement. However, in this method, it is possible to detect presence/absence of crystallinity, but the analogue quantitative detection is difficult and the in-plane distribution measurement with high accuracy is difficult. In particular, in the case of the bottom gate type method, since the influence of the pattern shape of a base metal is large, it is necessary to evaluate the in-plane crystallinity distribution on the pattern. In the case where a plurality of beams are used to improve the tact, there is a case where the pattern dependency is large, in particular, depending on the power density and profile of each beam. Thus, the necessity to quantitatively evaluate the crystallinity distribution on the pattern with high accuracy at high speed is generated.

As described above, in this embodiment, at the time of the inspection process of crystallinity of the p-Si film 23, the irradiation light Lout is irradiated with the LED 12 to the p-Si film 23 and the a-Si film 230, and the interference fringe image of the p-Si film 23 and the a-Si film 230 (interference image data D1) is obtained. Also, in the image processing computer 15, the (reflective) optical step between the p-Si film 23 (crystallized region 51) and the a-Si film 230 (uncrystallized region 50) is obtained, and one or both of sorting of the p-Si film 23 and calculation of the control amount of crystallinity is evaluated based on the obtained (reflective) optical step. Thus, the sorting more accurate compared to that of the existing art is realized, and the new control (control of crystallinity) may be realized. Therefore, in formation of the Si thin film utilizing crystallinity by laser annealing, it is possible to evaluate the crystallinity with high accuracy in comparison with the existing art, and thereby it is possible to improve the yield rate. For example, in the case where the gradation of the CCD camera 14 is 12-bit, the evaluation with accuracy of 1/4096 is possible. Thus, even in the case where the difference in the power density or the like is generated on the object to be irradiated (a-Si film 230) due to slight difference in the diameter of a laser beam caused by slight difference in a focus position and difference of divergence angle, or slight aberration of the optical systems or the like, it is possible to control crystallinity with the semiconductor laser at the time of the annealing treatment. It is possible to reduce the difference in the size of the crystal grain, and the difference in other characteristics between the irradiation regions on the p-Si film 23. Moreover, it is possible to perform the inspection of crystallinity which is non-contact and non-destructive to the Si-thin film substrate 2, and thus it is possible to monitor crystallinity with high reproducibility in a short time. For example, one spot area of several μm is measured by consuming integration time of several minutes in typical Raman spectrometry method, while areas of the number corresponding to the number of pixels in the CCD may be measured in several seconds in the method of this embodiment. That is, the measurement is performed 10⁶ times faster in comparison with the existing art in terms of one-area measurement.

Specifically, at the time of sorting of the p-Si film 23, sorting of the p-Si film 23 is performed by utilizing the correlation between the obtained (reflective) optical step, the light irradiation intensity at the time of obtaining the interference fringe image, and the electric properties expected to be obtained in the p-Si film 23. Thereby, the effects as described above may be obtained.

Moreover, since the evaluation at extremely-high speed is realized in comparison with that of the existing evaluation method, the real-time measurement is possible. Therefore, the real-time feed back is possible while performing the annealing treatment.

In the existing method, the physical property change of the semiconductor thin film generated according to the annealing intensity, and the refractive index change accompanied thereby are detected by using the reflection light amount change obtained through the use of a reflective spectrometry microscope or the like, and response to the annealing intensity is adjusted. On the other hand, in this embodiment, the refractive index change caused by the physical property change is detected by using the optical phase change obtained through the use of the light interference method, but not by using the light amount change. Therefore, in this embodiment, it is possible to detect the refractive index change with high accuracy by one order of magnitude or more in comparison with the existing method. Moreover, it is possible to correctively measure the in-plane distribution on the pattern at the same time, and thus it is possible to observe at high speed the distribution of microcrystallinity which has been difficult to observe. Thus, even in the annealing conditions which have been evaluated as identical, it can be seen that there is a case where these conditions are different. According to Weber Fechner's law, it is said that step-shaped luminance difference which may be viewed by human beings is 1% or less. However, with the evaluation technique of this embodiment, upstream control of the process is possible, and it is possible to realize manufacture of a thin film transistor at a high yield rate.

At the time of obtaining the interference fringe image of the p-Si film 23 and the a-Si film 230 (interference fringe image data D1), in the case where blue light (light having a wavelength region of approximately 350 nm to 400 nm both inclusive) is used as light irradiated to the p-Si film 23 and the a-Si film 230 (irradiation light Lout), the measurement with higher sensitivity is possible as illustrated in FIG. 7.

At the time of the annealing treatment, in the case where the laser light L1 is irradiated through the use of a plurality of laser light sources, it is possible to perform the annealing treatment in a short time by improving the throughput in the annealing treatment. Even in the case where the plurality of laser light sources are used in this manner, by performing the above-described inspection process, it is possible to suppress the influence of the variation in the laser light intensity, and it is possible to reduce the in-plane variation of the characteristics of the p-Si film 23.

Moreover, with the control signal S supplied form the control computer 16, the LED 12, the objective lens 13, the beam splitter 17, and the CCD camera 14 are relatively displaced to the Si-thin film substrate 2 mounted on the movable stage 11, and thus it is possible to obtain the interference fringe image at a plurality of points on the p-Si film 23 and the a-Si film 230, and it is possible to perform the inspection at the plurality of points.

### 2. Modification and Application Example

Although the present invention has been described with the embodiment hereinbefore, the preset invention is not limited to the embodiment, and various modifications may be made.

For example, in the above embodiment, the case were the blue light (light having a wavelength region of approximately 350 nm to 400 nm both inclusive) is used as the irradiation light Lout at the time of obtaining the interference fringe image of the p-Si film 23 (interference fringe image data D0 has been described. However, the wavelength region of the irradiation light Lout is not limited to this. In addition, the image pickup measures at the time of obtaining the interference fringe image is not limited to the objective lens 13 and the CCD camera 14 described in the above embodiment, and other optical systems may be used.

In the above embodiment, the case where the laser light L1 is irradiated through the use of the semiconductor laser light source at the time of forming the p-Si film 23 (at the time of the annealing treatment) has been described. However, for example, other types of laser light sources including a gas laser such as an excimer laser may be used.

In the above embodiment, the case where the heating treatment is directly applied on the a-Si film 230 by irradiating the laser light L1 to the a-Si film 230 in the step of forming the p-Si film 23 has been described. However, it is not limited to this case. That is, the heating treatment may be indirectly applied on the a-Si film 230 by irradiating the laser light L1 to a light absorption layer (not illustrated in the figure) on the a-Si film 230.

Moreover, for example, as illustrated in FIG. 10, the p-Si film 23 described in the above embodiment may be applied to a TFT substrate 3 including a bottom gate type thin film transistor (TFT) used in manufacture of a liquid crystal display and an organic EL display. Specifically, in the Si thin film substrate 2 after the inspection process of the above embodiment has been performed thereto, interlayer insulating films 251 and 252, a wiring 26, a planarized film 27, and a transparent conductive film 28 are formed and stacked in this order on the p-Si film 23, for example, through the use of photolithography method. At that time, the interlayer insulating film 251 is composed of, for example, silicon nitride (SiNₓ), and the interlayer insulating film 252 is composed of, for example, silicon oxide (SiO₂). Moreover, the wiring 26 is composed of, for example, aluminum (Al), the planarized film 27 is composed of, for example, acryl resin or the like, and the transparent conductive film 28 is composed of, for example, ITO (indium tin oxide). Although FIG. 10 illustrates the TFT substrate including the bottom gate type TFT, for example, the semiconductor thin film formed by using the present invention may be applied to the TFT substrate including a top gate type TFT. Moreover, the use of the semiconductor thin film formed by using the present invention is not limited to formation of such a TFT, but may be applied to other semiconductor elements.

Moreover, in the above embodiment, although the Si thin film (the a-Si film 230, the p-Si film 23, and the microcrystalline Si film) is used as an example of the amorphous semiconductor thin film and the crystalline semiconductor thin film, it is not limited to this case. That is, the present invention may be applied to a semiconductor thin film other than the Si thin film (all semiconductor thin films capable of measuring an optical step between an irradiation region and a non-irradiation region, such as a SiGe thin film).

The present application contains subject matter related to that disclosed in Japan Priority Patent Application JP 2009-024470 filed in the Japanese Patent Office on Feb. 5, 2009, the entire contents of which is hereby incorporated by reference.

It should be understood by those skilled in the art that various modifications, combinations, sub combinations and alternations may occur depending on design requirements and other factors insofar as they are within the scope of the appended claims or the equivalents thereof.

What is claimed is:

1. A method of forming a semiconductor thin film comprising the steps of:
forming an amorphous semiconductor thin film on a substrate;
partially forming a crystalline semiconductor thin film for each element region by irradiating laser light to the amorphous semiconductor thin film to selectively perform a heating treatment on the amorphous semiconductor thin film, and crystallizing an amorphous semiconductor thin film corresponding to an irradiation region; and
inspecting crystallinity of the crystalline semiconductor thin film, wherein
the inspection step includes the steps of
obtaining an optical step based on an optical phase difference between a crystallized region and an uncrystallized region by irradiating light to the crystalline semiconductor thin film and the amorphous semiconductor thin film, and
evaluating one or both of sorting of the crystalline semiconductor thin film and control of crystallinity of the crystalline semiconductor thin film, based on the obtained optical step.

2. The method of forming a semiconductor thin film according to claim 1, wherein
in the evaluation step, the sorting of the crystalline semiconductor thin film or the control of the crystallinity of the crystalline semiconductor thin film is performed through use of correlation between the obtained optical step, light irradiation intensity in the step of obtaining the optical step, and electric properties obtained in the crystalline semiconductor thin film.

3. The method of forming a semiconductor thin film according to claim 1, wherein
the optical step and a distribution of the optical step are obtained by obtaining an interference fringe image of the crystalline semiconductor thin film and the amorphous semiconductor thin film based on reflection light of the irradiation light.

4. The method of forming a semiconductor thin film according to claim 1, wherein light having a wavelength region of 350 nm to 400 nm both inclusive is used as the irradiation light in the step of obtaining the optical step.

5. The method of forming a semiconductor thin film according to claim 1, wherein the heating treatment is indirectly performed on the amorphous semiconductor thin film by irradiating the laser light to a light absorption layer in the step of forming the crystalline semiconductor thin film.

6. The method of forming a semiconductor thin film according to claim 1, wherein the laser light is irradiated through use of a semiconductor laser light source in the step of forming the crystalline semiconductor thin film.

7. The method of forming a semiconductor thin film according to claim 1, wherein the crystalline semiconductor thin film is used in formation of a TFT (thin film transistor).

8. The method of forming a semiconductor thin film according to claim 1, wherein the crystalline semiconductor thin film and the amorphous semiconductor thin film is a Si (silicon) thin film.

9. The method of forming a semiconductor thin film according to claim 8, wherein the crystalline semiconductor thin film is a polycrystalline Si thin film or a microcrystalline Si thin film.

10. The method of forming a semiconductor thin film according to claim 1, wherein an optical step in a region of a predetermined base pattern in the crystallized region is obtained in the step of obtaining the optical step.

11. The method of forming a semiconductor thin film according to claim 1, wherein an optical step in a region other than the predetermined base pattern in the crystallized region is obtained in the step of obtaining the optical step.

12. An inspection device of a semiconductor thin film comprising:
a stage mounting a substrate on which a crystalline semiconductor thin film is partially formed for each element region by irradiating laser light to an amorphous semiconductor thin film on the substrate to selectively perform a heating treatment on the amorphous semiconductor thin film, and crystallizing an irradiation region;
a light source irradiating light to the crystalline semiconductor thin film and the amorphous semiconductor thin film;
a derivation section obtaining an optical step based on an optical phase difference between a crystallized region and an uncrystallized region based on the light emitted from the light source; and
an evaluation section evaluating one or both of sorting of the crystalline semiconductor thin film and calculation of a control amount of crystallinity of the crystalline semiconductor thin film based on the optical step obtained in the derivation section.

13. The inspection device according to claim 12, further comprising:
a control section performing control to relatively displace optical systems of the light source and the derivation section to the substrate mounted on the stage.
